(19) United States
(12) Patent Application Publication
(10) Pub. No.: US 2019/0181278 A1
(43) Pub. Date: Jun. 13, 2019

(54) COMPOSITION FOR FORMING SOLAR CELL ELECTRODE AND ELECTRODE FABRICATED USING THE SAME

(71) Applicant: Samsung SDI Co., Ltd., Yongin-si (KR)

(72) Inventors: Gun Young HEO, Suwon-si (KR); Ye Jin KIM, Suwon-si (KR); Chul Kyu KIM, Suwon-si (KR); Hyun Jin KOO, Suwon-si (KR); Sung Bin CHO, Suwon-si (KR)

(21) Appl. No.: 16/011,951

(22) Filed: Jun. 19, 2018

(30) Foreign Application Priority Data
Dec. 7, 2017 (KR) 10-2017-0167840

(51) Int. Cl. H01L 31/0224; H01L 51/44; H01L 31/0216

(52) U.S. Cl. CPC H01L 31/022425; H01L 31/02167; H01L 51/441

(57) ABSTRACT

A composition for solar cell electrodes and a solar cell electrode prepared using the same, the composition including a conductive powder; a glass frit; an organic vehicle; a slip agent; and a thixotropic agent, wherein the composition has an angular velocity of 0.1 rad/sec to 80 rad/sec, as measured for tan δ max under conditions of 23 ° C. and 0.1 rad/sec to 1,000 rad/sec.

### CROSS-REFERENCE TO RELATED APPLICATION

Korean Patent Application No. 10-2017-0167840, filed on Dec. 7, 2017 in the Korean Intellectual Property Office, and entitled: “Composition for Forming Solar Cell Electrode and Electrode Fabricated using the Same,” is incorporated by reference herein in its entirety.

### BACKGROUND

### 1. Field

Embodiments relate to a composition for solar cell electrodes and an electrode fabricated using the same.

### 2. Description of the Related Art

With depletion of fossil fuel energy resources, solar cells have attracted attention as a new alternative energy source. Solar cells generate electricity using the photovoltaic effect of a p-n junction which converts photons of light, e.g., sunlight, into electricity. In a solar cell, front and rear electrodes may be formed on upper and lower surfaces of a semiconductor wafer or substrate having a p-n junction, respectively. Then, the photovoltaic effect at the p-n junction may be induced by, e.g., sunlight, entering the semiconductor wafer and electrons generated by the photovoltaic effect at the p-n junction may provide electric current to the outside through the electrodes. The electrodes of the solar cell may be formed on the wafer by applying, patterning, and baking an electrode paste.

### SUMMARY

Embodiments are directed to a composition for solar cell electrodes and an electrode fabricated using the same.

The embodiments may be realized by providing a composition for solar cell electrodes, the composition including a conductive powder; a glass frit; an organic vehicle; a slip agent; and a thixotropic agent, wherein the composition has an angular velocity of 0.1 rad/sec to 80 rad/sec, as measured for tan δ max under conditions of 23° C. and 0.1 rad/sec to 1,000 rad/sec.

The composition may have a tan δ max of about 11 or less, as measured under conditions of 23° C. and 0.1 rad/sec to 1,000 rad/sec.

The composition may have a storage modulus of about 3,500 Pa or less, as measured under conditions of 23° C. and 1 rad/sec.

The organic vehicle may include a first binder resin having a weight average molecular weight of about 20,000 to about 200,000.

The organic vehicle may further include a second binder resin having a number average molecular weight of about 500 to about 5,000.

The first binder resin may be present in an amount of about 0.1 wt % to about 20 wt %, based on a total weight of the composition, and the second binder resin may be present in an amount of about 0.1 wt % to about 10 wt %, based on the total weight of the composition.

The thixotropic agent may include a bisamide thixotropic agent, and the thixotropic agent may be present in an amount of about 0.1 wt % to about 5 wt %, based on a total weight of the composition.

The slip agent may include a linear siloxane or a cyclic siloxane, and the slip agent may be present in an amount of about 0.1 wt % to about 5 wt %, based on a total weight of the composition.

The composition may further include a dispersant, wherein the dispersant is present in an amount of about 0.1 wt % to about 5 wt %, based on a total weight of the composition.

The composition may further include a plasticizer, a viscosity stabilizer, an anti-foaming agent, a pigment, a UV stabilizer, an antioxidant, or a coupling agent.

The embodiments may be realized by providing a solar cell electrode fabricated using the composition for solar cell electrodes according to an embodiment.

The embodiments may be realized by providing a composition for solar cell electrodes, the composition including 60 wt % to 95 wt % of a conductive powder; 0.1 wt % to 20 wt %, a glass frit; 1 wt % to 30 wt % an organic vehicle, the organic vehicle including a first binder resin having a weight average molecular weight of 20,000 to 200,000 and a second binder resin having a number average molecular weight of 500 to 5,000; 0.1 wt % to 5 wt % of a slip agent, the slip agent including a linear siloxane or a cyclic siloxane; and 0.1 wt % to 5 wt % of a bisamide thixotropic agent, all wt % being based on a total weight of the composition, wherein the composition has an angular velocity of 0.1 rad/sec to 80 rad/sec, as measured for tan δ max under conditions of 23° C. and 0.1 rad/sec to 1,000 rad/sec.

### BRIEF DESCRIPTION OF THE DRAWINGS

Features will be apparent to those of skill in the art by describing in detail exemplary embodiments with reference to the attached drawings in which:

FIG. 1 illustrates a schematic view of a solar cell according to one embodiment.

FIG. 2 illustrates a graph showing angular velocity-dependent storage modulus (G′), loss modulus (G″), and tan δ values of Example 1.

FIG. 3 illustrates a graph showing angular velocity-dependent storage modulus (G′), loss modulus (G″), and tan δ values of Comparative Example 1.

FIG. 4 illustrates an image of the pattern shape of Example 1 after baking.

FIG. 5 illustrates an image of the pattern shape of Comparative Example 1 after baking.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. As used herein, the term “or” is not an exclusive term. Like reference numerals refer to like elements throughout.

Composition for Solar Cell Electrodes

A composition for solar cell electrodes may include, e.g., a conductive powder; a glass frit; an organic vehicle; a slip agent; and a thixotropic agent. The composition may have an angular velocity (gel point) of, e.g., about 0.1 rad/sec to about 80 rad/sec, as measured for tan δ max under conditions of 23° C. and 0.1 rad/sec to 1,000 rad/sec. Within this range, the composition may be printed with a fine line-width of about 30 μm or less and may have improved ejectability from a mesh in screen printing. In addition, the composition may realize an electrode having a high aspect ratio due to a small line-width and a high line-height in screen printing, thereby reducing resistance of a solar cell while improving conversion efficiency of the solar cell. In an implementation, the composition may have an angular velocity of, e.g., about 0.1 rad/sec to about 70 rad/sec, as measured for tan δ max under conditions of 23° C. and 0.1 rad/sec to 1,000 rad/sec.

In an implementation, the composition for solar cell electrodes may have a tan δ max of about 11 or less, e.g. about 10.5 or less or about 1 to about 10.5, as measured under conditions of 23° C. and 0.1 rad/sec to 1,000 rad/sec. Within this range, the composition may be printed with a fine line-width and may realize an electrode having a high aspect ratio.

In an implementation, the composition for solar cell electrodes may have a storage modulus of less than about 3,500 Pa or less, e.g., about 3,200 Pa or less, about 400 Pa to about 3,200 Pa, or about 1,000 Pa to about 3,200 Pa, as measured under conditions of 23° C. and 1 rad/sec. Within this range, the composition may be printed with a fine line-width and can realize an electrode having a high aspect ratio.

In an implementation, the composition for solar cell electrodes may have a viscosity of about 100 kcPs to about 500 kcPs, e.g., about 100 kcPs to about 300 kcPs, as measured under conditions of 23° C. and 10 rpm. Within this range, the composition for solar cell electrodes may be used as a composition for solar cell electrodes.

Now, each component of the composition for solar cell electrodes according to an embodiment will be described in more detail.

Conductive Powder

The conductive powder may include at least one metal powder selected from among, e.g., silver, gold, platinum, palladium, aluminum, and nickel. In an implementation, the conductive powder may include silver (Ag) powder.

The conductive powder may have a nanometer or micrometer-scale particle size. For example, the conductive powder may have an average particle diameter of dozens to several hundred nanometers or may have an average particle diameter of several to dozens of micrometers. In an implementation, the conductive powder may be a mixture of two or more types of conductive powder having different particle sizes.

In an implementation, the conductive powder may have various particle shapes, e.g., a spherical, flake or amorphous particle shape.

In an implementation, the conductive powder may have an average particle diameter (D50) of about 0.1 μm to about 10 μm, e.g., about 0.5 μm to about 5 μm. Within this range, the composition may help reduce contact resistance and line resistance of a solar cell. Here, the average particle diameter may be measured using a Model 1064D particle size analyzer (CILAS Co., Ltd.) after dispersing the conductive powder in isopropyl alcohol (IPA) at 25° C. for 3 minutes via ultrasonication.

The conductive powder may be present in the composition in an amount of about 60 wt % to about 95 wt %, based on a total weight of the composition for solar cell electrodes. Within this range, the composition may help improve conversion efficiency of a solar cell and may be easily prepared in paste form. In an implementation, the conductive powder may be present in an amount of, e.g., about 70 wt % to about 95 wt % in the composition for solar cell electrodes. For example, the conductive powder may be present in an amount of about 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt % in the composition for solar cell electrodes.

Glass Frit

The glass frit may serve to form crystal grains of the conductive powder in an emitter region by etching an anti-reflection layer and melting the conductive powder during a baking process of the composition for solar cell electrodes. Further, the glass frit may help improve adhesion of the conductive powder to a wafer and may be softened to decrease the baking temperature during the baking process.

In an implementation, the glass frit may be a low-melting point glass frit having a glass transition temperature of, e.g., about 200° C. to about 300° C. Within this range of glass transition temperature, the composition may exhibit good properties in terms of contact resistance.

In an implementation, the glass frit may be a lead-free glass frit. For example, the glass frit may include at least one selected from among bismuth (Bi), tellurium (Te), lithium (Li), zinc (Zn), phosphorus (P), germanium (Ge), gallium (Ga), cerium (Ce), iron (Fe), silicon (Si), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), and manganese (Mn). In an implementation, the glass frit may be a bismuth-tellurium-zinc-lithium-oxide (Bi—Te—Zn—Li—O) glass frit.

The glass frit may have a suitable shape and size. In an implementation, the glass frit may have an average particle diameter (D50) of, e.g., about 0.1 m to about 10 μm. In an implementation, the glass frit may have a spherical or amorphous shape. Here, the average particle diameter (D50) may be measured using a Model 1064D particle size analyzer (CILAS Co., Ltd.) after dispersing the conductive powder in isopropyl alcohol (IPA) at 25° C. for 3 minutes via ultrasonication.

The glass frit may be prepared from metal and/or metal oxides by a suitable method. In an implementation, the glass frit may be prepared by mixing tellurium oxide, bismuth oxide, and, optionally other metals and/or metal oxides using a ball mill or a planetary mill, melting the mixture at about 800° C. to about 1,300° C., and quenching the melted mixture to 25° C., followed by pulverizing the obtained product using a disk mill, a planetary mill or the like.

In an implementation, the glass frit may be present in an amount of about 0.1 wt % to about 20 wt %, e.g., about 0.5 wt % to about 10 wt % or about 1.5 wt % to about 2 wt % in the composition for solar cell electrodes. Within this range, the glass frit may secure stability of a p-n junction under various sheet resistances, minimize serial resistance, and ultimately improve efficiency of a solar cell. For example, the glass frit may be present in an amount of about 0.1 wt %, 0.5 wt %, 1 wt %, 1.5 wt %, 2 wt %, 2.5 wt %, 3 wt %, 3.5 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt % in the composition for solar cell electrodes.

Organic Vehicle

The organic vehicle may impart suitable viscosity and rheological characteristics for printing to the composition for solar cell electrodes through mechanical mixing with inorganic components of the composition.

The organic vehicle may include, e.g., a binder resin, a solvent, or the like.

In an implementation, the solvent may include, e.g., hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, ethyl lactate, or 2,2,4-trimethyl-1,3-pentanediol monoisobutyrate (e.g., Texanol). These may be used alone or as a mixture thereof.

In an implementation, the binder resin may be selected from acrylate resins or cellulose resins. In an implementation, ethyl cellulose may be used as the binder resin. In an implementation, the binder resin may include, e.g., ethyl hydroxyethyl cellulose, nitrocellulose, blends of ethyl cellulose and phenol resins, alkyd resins, phenol resins, acrylate ester resins, xylene resins, polybutene resins, polyester resins, urea resins, melamine resins, vinyl acetate resins, rosin resins such as wood rosin, polymethacrylates of alcohols, or the like. These may be used alone or as a mixture thereof.

In an implementation, the binder resin may include a first binder resin having a weight average molecular weight of about 20,000 to about 200,000, e.g., about 20,000 to about 100,000. In an implementation, the binder resin may be a mixture of the first binder resin having a weight average molecular weight of about 20,000 to about 200,000 and a second binder resin having a number average molecular weight of about 500 to about 5,000, e.g., about 500 to about 3,000. When the binder resin is the mixture of the first binder resin having a weight average molecular weight in this range and the second binder resin having a number average molecular weight in this range, the composition solar cell electrodes can have an angular velocity of about 0.1 rad/sec to about 80 rad/sec, as measured for tan δ max under conditions of 23° C. and 0.1 rad/sec to 1,000 rad/sec.

In an implementation, the first binder resin may be present in an amount of about 0.1 wt % to about 20 wt %, e.g., about 0.1 wt % to about 10 wt %, in the composition for solar cell electrodes. In an implementation, the second binder resin may be present in an amount of about 0.1 wt % to about 10 wt %, e.g., about 0.1 wt % to about 5 wt %, in the composition for solar cell electrodes. Within these ranges, the composition solar cell electrodes may have an angular velocity of about 0.1 rad/sec to about 80 rad/sec, as measured for tan δ max under conditions of 23° C. and 0.1 rad/sec to 1,000 rad/sec.

In an implementation, the organic vehicle may be present in an amount of, e.g., about 1 wt % to about 30 wt % based on the total weight of the composition for solar cell electrodes. Within this range, the organic vehicle may provide sufficient adhesive strength and good printability to the composition. For example, the organic vehicle may be present in an amount of about 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %, based on the total weight of the composition for solar cell electrodes.

Slip Agent

In an implementation, the slip agent may include at least one of a linear siloxane and a cyclic siloxane.

In an implementation, the linear siloxane may be present in an amount of 5 wt % or less, e.g., about 0.1 wt % to about 5 wt %, in the composition for solar cell electrodes. Within this range, the composition solar cell electrodes may have an angular velocity of about 0.1 rad/sec to about 80 rad/sec, as measured for tan S max under conditions of 23° C. and 0.1 rad/sec to 1,000 rad/sec. For example, the linear siloxane may be present in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the composition for solar cell electrodes.

The linear siloxane may include, e.g., polymethylsiloxane, polyethylsiloxane, polydimethylsiloxane, or polydiethylsiloxane.

In an implementation, the cyclic siloxane may be present in an amount of 5 wt % or less, e.g., about 0.1 wt % to about 5 wt % in the composition for solar cell electrodes. Within this range, the composition solar cell electrodes may have an angular velocity of about 0.1 rad/sec to about 80 rad/sec, as measured for tan δ max under conditions of 23° C. and 0.1 rad/sec to 1,000 rad/sec. For example, the cyclic siloxane may be present in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the composition for solar cell electrodes.

The cyclic siloxane may be a cyclic siloxane compound having a ring of silicon-oxygen-silicon-oxygen. In an implementation, the cyclic siloxane may include, e.g., a substituted or unsubstituted cyclotrisiloxane, a substituted or unsubstituted cyclotetrasiloxane, a substituted or unsubstituted cyclopentasiloxane, a substituted or unsubstituted cyclohexasiloxane, a substituted or unsubstituted cycloheptasiloxane, a substituted or unsubstituted cyclooctasiloxane, a substituted or unsubstituted cyclononasiloxane, or a substituted or unsubstituted cyclodecasiloxane. As used herein, the term “substituted” means that at least one hydrogen atom coupled to silicon (Si) in the siloxane is substituted or replaced with a C₁ to C₅ alkyl group (e.g., a methyl group, an ethyl group, a propyl group, a butyl group, or a pentyl group), a C₂ to C₅ alkenyl group (e.g., a vinyl group), a C₆ to C₁₀ aryl group (e.g., phenyl group), or a C₁ to C₅ halogenated alkyl group (e.g., a trifluoropropyl group).

In an implementation, the cyclic siloxane compound may include, e.g., hexamethylcyclotrisiloxane, octamethylcyclotetrasiloxane, decamethylcyclopentasiloxane, dodecamethylcyclohexasiloxane, tetradecamethylcycloheptasiloxane, octadecamethylcyclononasiloxane, tetramethylcyclotetrasiloxane, hexaphenylcyclotrisiloxane, tetramethyl-tetravinylcyclotetrasiloxane such as 2,4,6,8-tetramethyl-2,4,6,8-tetravinylcyclotetrasiloxane, tris(trifluoropropyl)-trimethylcyclotrisiloxane such as 1,3,5-tris(3,3,3-trifluoropropyl)-1,3,5-trimethylcyclotrisiloxane, hexadecamethylcyclooctasiloxane, pentamethylcyclopentasiloxane, hexamethylcyclohexasiloxane, octaphenylcyclotetrasiloxane, triphenylcyclotrisiloxane, tetraphenylcyclotetrasiloxane, tetramethyl-tetraphenylcyclotetrasiloxane, tetravinyl-tetraphenylcyclotetrasiloxane, hexamethyl-hexavinylcyclohexasiloxane, hexamethyl-hexaphenylcyclohexasiloxane, or hexavinyl-hexaphenylcyclohexasiloxane.

In an implementation, the slip agent may be present in an amount of, e.g., about 0.1 wt % to about 5 wt % in the composition for solar cell electrodes. Within this range, the slip agent may help reduce the ratio of change in area of the composition and may help prevent an increase in resistance of a solar cell. For example, the slip agent may be present in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the composition for solar cell electrodes.

Thixotropic Agent

In an implementation, the thixotropic agent may include a bisamide thixotropic agent. The bisamide thixotropic agent may include a suitable bisamide thixotropic agent, e.g., Thixatrol Max (Elementis Co., Ltd.).

In an implementation, the thixotropic agent may be present in an amount of, e.g., about 0.1 wt % to about 5 wt % in the composition for solar cell electrodes. Within this range, the composition for solar cell electrodes may have an angular velocity of about 0.1 rad/sec to about 80 rad/sec, as measured for tan δ max under conditions of 23° C. and 0.1 rad/sec to 1,000 rad/sec. For example, the thixotropic agent may be present in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the composition for solar cell electrodes.

In an implementation, the composition for solar cell electrodes may be free from or essentially free from a castor oil thixotropic agent. If the composition for solar cell electrodes were to include a castor oil thixotropic agent, it may be difficult for the composition to have an angular velocity of about 0.1 rad/sec to about 80 rad/sec, as measured for tan δ max under conditions of 23° C. and 0.1 rad/sec to 1,000 rad/sec.

Dispersant

The composition for solar cell electrodes may further include a dispersant. The dispersant may include an acid dispersant. The acid dispersant may include a suitable acid dispersant, e.g., saturated or unsaturated acid dispersants including succinic acid dispersants and polycarboxylic acid dispersants such as a tri- or higher valent carboxylic acid dispersant.

In an implementation, the dispersant may further include an amine salt dispersant. The amine salt dispersant may include a suitable amine salt dispersant.

In an implementation, the dispersant may be present in an amount of, e.g., about 0.1 wt % to about 5 wt % in the composition for solar cell electrodes. Within this range, the dispersant may help reduce a rate of change in area of the composition and may help prevent an increase in the resistance of a solar cell. For example, the dispersant may be present in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the composition for solar cell electrodes.

Other Additives

In an implementation, the composition for solar cell electrodes may further include a suitable additive to enhance flowability, processability and stability, as desired. The additive may include, e.g., a plasticizer, a viscosity stabilizer, an anti-foaming agent, a pigment, a UV stabilizer, an antioxidant, a coupling agent, or the like. These may be used alone or as a mixture thereof. In an implementation, the additive may be present in an amount of, e.g., about 0.1 wt % to about 5 wt % in the composition for solar cell electrodes. For example, the additive may be present in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the composition for solar cell electrodes.

Solar Cell Electrode and Solar Cell Including the Same

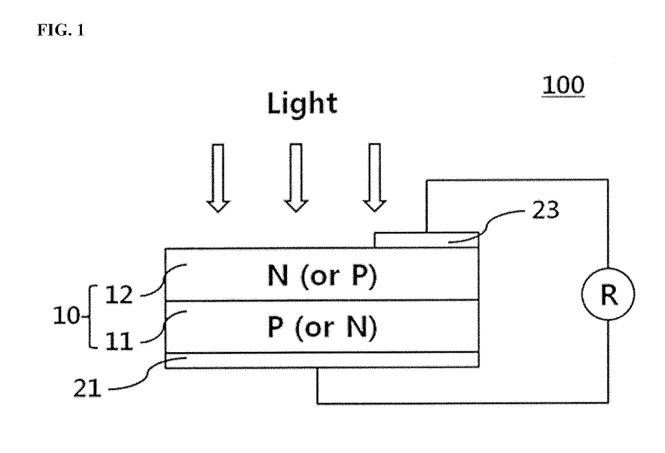

Other aspects of the embodiments relate to an electrode formed of the composition for solar cell electrodes and a solar cell including the same. FIG. 1 shows a solar cell in accordance with one embodiment.

Referring to FIG. 1, the solar cell 100 may be a rear electrode 21 and a front electrode 23, which may be formed by printing the composition for electrodes on a wafer or substrate 10 including a p-layer (or an n-layer) 11 and an n-layer (or a p-layer) 12 as an emitter, followed by baking. For example, a preliminary process of preparing the rear electrode may be performed by printing the composition on a back surface of the wafer and drying the printed composition at about 200° C. to about 40 0° C. for about 10 seconds to 60 seconds. Further, a preliminary process for preparing the front electrode may be performed by printing the composition on a front surface of the wafer and drying the printed composition. Then, the front electrode and the rear electrode may be formed by baking the wafer at about 400° C. to about 950° C., e.g., at about 700° C. to about 950° C., for about 30 seconds to 210 seconds.

Next, the embodiments will be described in more detail with reference to examples. However, it should be noted that these examples are provided for illustration only and should not be construed in any way as limiting.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

(A) 90 parts by weight of silver powder was mixed with (B) 2 parts by weight of a glass frit, thereby preparing a mixture. As an organic vehicle, (C1) 1 part by weight of ethyl cellulose and (C3) 5.6 parts by weight of Texanol were added to the mixture. Then, (D1) 0.35 parts by weight of polydimethylsiloxane as a slip agent, (E1) 0.6 parts by weight of a bisamide thixotropic agent, and (F3) 0.45 parts by weight of a polycarboxylic acid dispersant were added to the mixture, followed by mixing and kneading in a 3-roll kneader, thereby preparing a composition for solar cell electrodes.

### Examples 2 to 8

A composition for solar cell electrodes was prepared in the same manner as in Example 1 except that the content (in parts by weight) of each component was changed as listed in Table 1.

### Comparative Examples 1 to 5

A composition for solar cell electrodes was prepared in the same manner as in Example 1 except that the content (in parts by weight) of each component was changed as listed in Table 2.

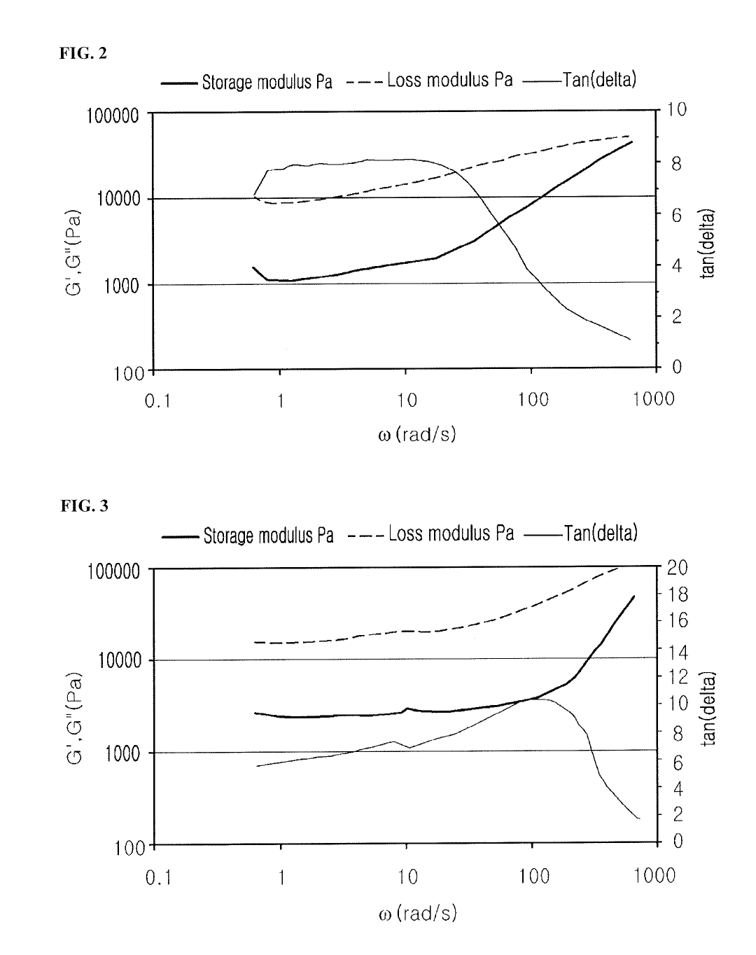

Each of the compositions for solar cell electrodes prepared in the Examples and Comparative Examples was evaluated as to the following properties. Results are shown in Table 1, Table 2, FIG. 2 and FIG. 3.

(1) Storage modulus (unit: Pa, @1 rad/sec): Storage modulus of each of the compositions for solar cell electrodes prepared in the Examples and Comparative Examples was evaluated using a rotational rheometer (ARES G2, TA Instruments) by a frequency sweep method. Here, the measurement of storage modulus of each composition was performed under conditions of 23° C. and 0.1 rad/sec to 1,000 rad/sec (angular velocity). The storage modulus was determined by a storage modulus value at an angular velocity of 1 rad/sec.

(2) Tan δ max: Tan δ max of each of the compositions for solar cell electrodes prepared in the Examples and Comparative Examples was evaluated using a rotational rheometer (ARES G2, TA Instruments) by a frequency sweep method. Here, measurement of tan δ values was performed under conditions of 23° C. and 0.1 rad/sec to 1,000 rad/sec (angular velocity), followed by finding the highest value among the measured tan δ values.

(3) Gel point (angular velocity measured for tan δ max) (unit: rad/sec, @maximum tan δ): Gel point (angular velocity measured for tan δ max) of each of the compositions for solar cell electrodes prepared in the Examples and Comparative Examples was evaluated by a frequency sweep method.

(4) Viscosity (unit: kcPs, @10 rpm, @23° C.): Viscosity of each of the compositions for solar cell electrodes prepared in the Examples and Comparative Examples was evaluated under conditions of 10 rpm and 23° C. using a Brookfield viscometer.

An electrode was fabricated using each of the compositions for solar cell electrodes of the Examples and Comparative Examples and then evaluated as to the properties listed in Tables 1 and 2. Results are shown in Table 1, Table 2, and FIG. 2 to FIG. 5.

Each of the compositions for solar cell electrodes prepared in the Examples and Comparative Examples was deposited over a front surface of a wafer (sheet resistance: 70 Ω/sq.) by screen printing in a predetermined pattern, followed by drying in an IR drying furnace. Then, an aluminum paste was printed on the entire back surface of the wafer and dried in the same manner as above. A cell formed according to this procedure was subjected to baking at a temperature of 400° C. to 900° C. for 30 seconds to 50 seconds in a belt-type baking furnace, thereby fabricating a solar cell. The solar cell was evaluated as to printability, flooding, patternability 1, and patternability 2 according to the following criteria.

(1) Printability: Disconnection of the obtained pattern was checked, followed by evaluation of printability according to the following criteria.

∘: The number of disconnected lines: less than 5

x: The number of disconnected lines: greater than or equal to 5

(2) Flooding: Each of the compositions for solar cell electrodes was deposited on a silicon wafer for solar cells to prepare a specimen. A specimen that exhibited uniform flooding upon deposition was rated as “good” and a specimen that did not exhibit uniform flooding upon deposition and was partially impossible to redeposit was rated as “poor”.

(3) Patternability 1: Width of the obtained pattern was observed with a laser microscope.

∘: Standard deviation of line-width values: less than 3 μm, Rz: less than 15 μm

Δ: Standard deviation of line-width values: greater than or equal to 3 μm and less than 5 μm, Rz: greater than or equal to 15 μm and less than 20 μm

x: Standard deviation of line-width values: greater than or equal to 5 μm, Rz: greater than or equal to 20 μm

(4) Patternability 2: Height and width of the pattern were observed with a laser microscope and aspect ratio (ratio of height to width) of the pattern was calculated.

∘: Aspect ratio of greater than or equal to 25%

Δ: Aspect ratio of greater than or equal to 20% and less than 25%

x: Aspect ratio of less than 20%

TABLE 1

| | | Example | | | | | | | |
|---|---|---|---|---|---|---|---|---|---|
| | | 1 | 2 | 3 | 4 | 5 | 6 | 7 | 8 |
| (A) | | 90 | 90 | 90 | 90 | 90 | 90 | 90 | 90 |
| (B) | | 2 | 2 | 2 | 2 | 2 | 2 | 2 | 2 |
| (C) | (C1) | 1 | 0.6 | 1 | 1 | 0.2 | 1 | 1 | 0.4 |
| | (C2) | — | 0.4 | — | — | 0.8 | — | — | 0.8 |
| | (C3) | 5.6 | 5.6 | 5.6 | 5.6 | 5.6 | 5.6 | 5.6 | 5.6 |
| (D) | (D1) | 0.35 | 0.35 | — | 0.25 | 0.35 | 0.35 | 0.35 | 0.4 |
| | (D2) | — | — | 0.35 | 0.1 | — | — | — | — |
| (E) | (E1) | 0.6 | 0.6 | 0.6 | 0.6 | 0.6 | 0.6 | 0.6 | 0.4 |
| | (E2) | — | — | — | — | — | — | — | — |
| (F) | (F1) | — | 0.1 | — | — | — | — | 0.2 | — |
| | (F2) | — | — | — | — | — | 0.45 | — | — |
| | (F3) | 0.45 | 0.35 | 0.45 | 0.45 | 0.45 | — | 0.25 | 0.4 |

| | | | | | | | | |
|---|---|---|---|---|---|---|---|---|
| Storage modulus | 2610 | 1778 | 1818 | 2719 | 1333 | 1253 | 1297 | 3159 |
| Tan δ max | 8.2 | 8.1 | 7.7 | 7.5 | 8.4 | 8.1 | 10.5 | 6.7 |
| Gel point | 10.0 | 15.8 | 7.9 | 12.5 | 19.9 | 40.0 | 62.8 | 10.0 |
| Viscosity | 256 | 273 | 251 | 264 | 271 | 166 | 247 | 283 |
| Printability | ∘ | ∘ | ∘ | ∘ | ∘ | ∘ | ∘ | ∘ |
| Flooding | Good | Good | Good | Good | Good | Good | Good | Good |
| Patternability 1 | ∘ | Δ | ∘ | ∘ | Δ | Δ | Δ | Δ |
| Patternability 2 | ∘ | ∘ | ∘ | ∘ | ∘ | Δ | Δ | ∘ |

TABLE 2

| | | Comparative Example | | | | |
|---|---|---|---|---|---|---|
| | | 1 | 2 | 3 | 4 | 5 |
| (A) | | 90 | 90 | 90 | 90 | 90 |
| (B) | | 2 | 2 | 2 | 2 | 2 |
| (C) | (C1) | 1 | 1 | 0.9 | 0.9 | 1 |
| | (C2) | — | — | 0.6 | 0.45 | — |
| | (C3) | 5.6 | 5.6 | 5.28 | 5.37 | 5.6 |
| (D) | (D1) | 0.35 | 0.35 | 0.4 | 0.4 | 0.15 |
| | (D2) | — | — | — | — | 0.20 |
| (E) | (E1) | 0.6 | — | 0.37 | 0.43 | 0.6 |
| | (E2) | — | 0.6 | — | — | — |
| (F) | (F1) | 0.45 | — | 0.45 | 0.45 | 0.45 |
| | (F2) | — | — | — | — | — |
| | (F3) | — | 0.45 | — | — | — |

| | | | | | |
|---|---|---|---|---|---|
| Storage modulus | 2581 | 1570 | 2221 | 2861 | 2295 |
| Tan δ max | 10.6 | 8.1 | 12.3 | 12.1 | 8.5 |
| Gel point | 99.6 | 99.6 | 99.6 | 125.4 | 99.6 |
| Viscosity | 260 | 254 | 341 | 286 | 175 |
| Printability | x | x | x | x | x |
| Flooding | Poor | Good | Poor | Poor | Good |
| Patternability 1 | x | Δ | x | Δ | Δ |
| Patternability 2 | Δ | Δ | ∘ | ∘ | Δ |

(A) Silver powder: Average particle diameter: 2.0 μm (AG-5-11F, Dowa Hightech Co., Ltd.)

(B) Glass flit: Glass transition temperature: 270° C., average particle diameter: 2.0 μm (ABT-1, Ashai Glass Co., Ltd.)

(C) Organic vehicle

(C1) Ethyl cellulose: Weight average molecular weight: 40,000 (STD4, Dow Chemical Company)

(C2) Rosin: Number average molecular weight: 600 (Foral 85E, Eastman Chemical)

(C3) Texanol (Eastman Chemical)

(D) Slip agent

(D1) Polydimethylsiloxane (KF-96, ShinEtsu Chemical)

(D2) Cyclopentasiloxane (PMX-245, Dow Corning Corporation)

(E) Thixotropic agent

(E1) Bisamide thixotropic agent (Thixatrol Max, Elementis Co., Ltd.)

(E2) Caster oil thixotropic agent (Thixatrol ST, Elementis Co., Ltd.)

(F) Dispersant

(F1) Amine salt dispersant (TDO, Akzonobel Chemical)

(F2) Octadecenyl succinic acid dispersant (KD-16, Croda Advanced Materials)

(F3) Polycarboxylic acid dispersant (MALIALIM, NOF Corporation)

As shown in Table 1 and FIG. 2, it may be seen that the composition for solar cell electrodes according to the Examples had an angular velocity of 0.1 rad/sec to 80 rad/sec, as measured for tan δ max under conditions of 23° C. and 0.1 rad/sec to 1,000 rad/sec. As a result, the composition for solar cell electrodes according to the Examples facilitated fine line-width printing and thus exhibited good printability and patternability and uniform flooding, as shown in FIG. 4.

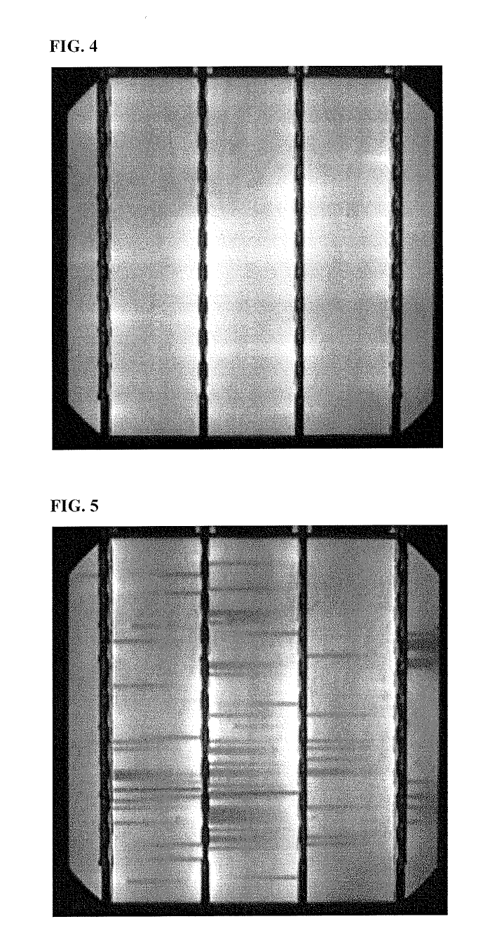

Conversely, the composition for solar cell electrodes of Comparative Example 1 had an angular velocity outside the range of 0.1 rad/sec to 80 rad/sec, as measured for tan δ max under conditions of 23° C. and 0.1 rad/sec to 1,000 rad/sec. Thus, in fine line-width printing, the composition of Comparative Example 1 exhibited poor printability and patternability and non-uniform flooding, as shown in FIG. 5.

By way of summation and review, in a solar cell, conversion efficiency, e.g., the ratio of useful output of the solar cell to input, in energy terms, may be improved. In order to improve conversion efficiency of the solar cell, preparing a proper electrode paste through adjustment of the size and mixing ratio of conductive powder particles or through surface treatment of the conductive powder particles may be considered. However, this method alone may have a limitation in increasing conversion efficiency of the solar cell. In addition, a method of obtaining desirable sintering density or electrode resistance by mixing conductive powders having different particle diameters may have limited printability and patternability. An electrode paste that may help improve conversion efficiency of a solar cell through improvement of organic materials used therefor and may exhibit improved ejectability from a mesh in screen printing, thereby realizing a front electrode that has a high aspect ratio due to small line-width and high line-height, may be considered.

In order to improve printability of pastes for solar cell electrodes, dispersibility may be increased using surface-treated conductive particles or by adjusting the size and mixing ratio of conductive particles. In addition, an acrylate binder may be used instead of cellulose binder resins. However, the former may have a limitation in terms of electrical properties, whereas the latter may have advantages in that the acrylate binder may be prepared by a simpler process than cellulose binder resins, provide desired properties to pastes through combination of various monomers, and exhibit good dispersion due to low residual carbon content and the presence of a polar functional group in polymer side groups thereof. However, the latter may have relatively poor printability (thixotropy), as compared with cellulose binder resins. The above-described methods may be material approaches, and development of a rheological approach may be considered.

The embodiments may provide a composition for solar cell electrodes that may be printed with a fine line-width of about 30 μm or less.

The embodiments may provide a composition for solar cell electrodes that may exhibit improved ejectability from a mesh in screen printing.

The embodiments may provide a composition for solar cell electrodes that may realize an electrode having a high aspect ratio due to a small line-width and a high line-height in screen printing, thereby reducing resistance of a solar cell while improving conversion efficiency of the solar cell.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A composition for solar cell electrodes, the composition comprising:
a conductive powder;
a glass frit;
an organic vehicle;
a slip agent; and
a thixotropic agent,
wherein the composition has an angular velocity of 0.1 rad/sec to 80 rad/sec, as measured for tan δ max under conditions of 23° C. and 0.1 rad/sec to 1,000 rad/sec.

2. The composition as claimed in claim 1, wherein the composition has a tan δ max of about 11 or less, as measured under conditions of 23° C. and 0.1 rad/sec to 1,000 rad/sec.

3. The composition as claimed in claim 1, wherein the composition has a storage modulus of about 3,500 Pa or less, as measured under conditions of 23° C. and 1 rad/sec.

4. The composition as claimed in claim 1, wherein the organic vehicle includes a first binder resin having a weight average molecular weight of about 20,000 to about 200,000.

5. The composition as claimed in claim 4, wherein the organic vehicle further includes a second binder resin having a number average molecular weight of about 500 to about 5,000.

6. The composition as claimed in claim 5, wherein:
the first binder resin is present in an amount of about 0.1 wt % to about 20 wt %, based on a total weight of the composition, and
the second binder resin is present in an amount of about 0.1 wt % to about 10 wt %, based on the total weight of the composition.

7. The composition as claimed in claim 1, wherein:
the thixotropic agent includes a bisamide thixotropic agent, and
the thixotropic agent is present in an amount of about 0.1 wt % to about 5 wt %, based on a total weight of the composition.

8. The composition as claimed in claim 1, wherein:
the slip agent includes a linear siloxane or a cyclic siloxane, and
the slip agent is present in an amount of about 0.1 wt % to about 5 wt %, based on a total weight of the composition.

9. The composition as claimed in claim 1, further comprising a dispersant, wherein the dispersant is present in an amount of about 0.1 wt % to about 5 wt %, based on a total weight of the composition.

10. The composition as claimed in claim 1, further comprising a plasticizer, a viscosity stabilizer, an anti-foaming agent, a pigment, a UV stabilizer, an antioxidant, or a coupling agent.

11. A solar cell electrode fabricated using the composition for solar cell electrodes as claimed in claim 1.

12. The solar cell electrode as claimed in claim 11, wherein the composition has a tan δ max of about 11 or less, as measured under conditions of 23° C. and 0.1 rad/sec to 1,000 rad/sec.

13. The solar cell electrode as claimed in claim 11, wherein the composition has a storage modulus of about 3,500 Pa or less, as measured under conditions of 23° C. and 1 rad/sec.

14. The solar cell electrode as claimed in claim 11, wherein the organic vehicle includes a first binder resin having a weight average molecular weight of about 20,000 to about 200,000.

15. The solar cell electrode as claimed in claim 14, wherein the organic vehicle further includes a second binder resin having a number average molecular weight of about 500 to about 5,000.

16. The solar cell electrode as claimed in claim 15, wherein:
the first binder resin is present in an amount of about 0.1 wt % to about 20 wt %, based on a total weight of the composition, and
the second binder resin is present in an amount of about 0.1 wt % to about 10 wt %, based on the total weight of the composition.

17. The solar cell electrode as claimed in claim 11, wherein:
the thixotropic agent includes a bisamide thixotropic agent, and
the thixotropic agent is present in an amount of about 0.1 wt % to about 5 wt %, based on a total weight of the composition.

18. The solar cell electrode as claimed in claim 11, wherein:
the slip agent includes a linear siloxane or a cyclic siloxane, and
the slip agent is present in an amount of about 0.1 wt % to about 5 wt %, based on a total weight of the composition.

19. The solar cell electrode as claimed in claim 11, wherein the composition further includes a dispersant, wherein the dispersant is present in an amount of about 0.1 wt % to about 5 wt %, based on a total weight of the composition.

20. The solar cell electrode as claimed in claim 11, wherein the composition further includes a plasticizer, a viscosity stabilizer, an anti-foaming agent, a pigment, a UV stabilizer, an antioxidant, or a coupling agent.

21. A composition for solar cell electrodes, the composition comprising:
60 wt % to 95 wt % of a conductive powder;
0.1 wt % to 20 wt %, a glass frit;
1 wt % to 30 wt % an organic vehicle, the organic vehicle including a first binder resin having a weight average molecular weight of 20,000 to 200,000 and a second binder resin having a number average molecular weight of 500 to 5,000;
0.1 wt % to 5 wt % of a slip agent, the slip agent including a linear siloxane or a cyclic siloxane; and
0.1 wt % to 5 wt % of a bisamide thixotropic agent, all wt % being based on a total weight of the composition,
wherein the composition has an angular velocity of 0.1 rad/sec to 80 rad/sec, as measured for tan δ max under conditions of 23° C. and 0.1 rad/sec to 1,000 rad/sec.
